(19) United States
(12) Patent Application Publication
(10) Pub. No.: US 2026/0353788 A1
(43) Pub. Date: Nov. 5, 2026

(54) STACKED TRANSISTORS AND METHODS OF FORMING THE SAME

(71) Applicant: Taiwan Semiconductor Manufacturing Co., Ltd., Hsinchu (TW)

(72) Inventors: Kai-Chieh Yang, New Taipei City (TW); Szu-Hua Chen, Tainan City (TW); Min-Chang Tsai, Tainan City (TW); Wei-Yen Woon, Taoyuan City (TW); Szuya Liao, Zhubei (TW)

(21) Appl. No.: 19/738,702

(22) Filed: Jul. 13, 2026

Related U.S. Application Data
(63) Continuation of application No. 19/053,836, filed on Feb. 14, 2025.
(60) Provisional application No. 63/706,080, filed on Oct. 11, 2024.

(51) Int. Cl. H10D 84/85; H10D 30/00; H10D 30/01; H10D 62/10; H10D 64/01; H10D 64/66; H10D 84/01

(52) U.S. Cl. CPC H10D 84/851; H10D 30/0191; H10D 30/502; H10D 62/121; H10D 64/017; H10D 64/669; H10D 84/0177; H10D 84/856

(57) ABSTRACT

Complementary Field-Effect Transistors (CFETs) are formed having different combinations of work function metal layers that produce different threshold voltages. A method includes forming first nanostructures over a first region of a substrate; forming second nanostructures over a second region of the substrate; forming third nanostructures over a third region of the substrate; depositing a first gate electrode layer on the first nanostructures; depositing a second gate electrode layer on the second nanostructures and on the first gate electrode layer on the first nanostructures; depositing a third gate electrode layer on the third nanostructures, on the second gate electrode layer on the second nanostructures, and on the second gate electrode layer on the first nanostructures; and depositing a fourth gate electrode layer on the third gate electrode layer, on the first nanostructures, on the second nanostructures, and on the third nanostructures.

### PRIORITY CLAIM AND CROSS-REFERENCE

This application is a continuation of U.S. Patent Application No. 19/053,836, filed on Feb. 14, 2025, which claims the benefit of the following provisionally filed U.S. Patent application: Application No. 63/706,080, filed on Oct. 11, 2024, each application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional view of example Complementary Field-Effect Transistors (CFETs), in accordance with some embodiments.

FIGS. 2, 3, and 4 illustrate various views of intermediate stages in the manufacturing of CFETs, in accordance with some embodiments.

FIGS. 5, 6, 7, 8, 9, 10, 11, 12, 13, 14, 15, 16, 17, 18, and 19 illustrate cross-sectional views of intermediate stages in the manufacturing of gate structures, in accordance with some embodiments.

FIGS. 20 and 21 illustrate cross-sectional views of intermediate stages in the manufacturing of CFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and methods of forming the same are provided. According to various embodiments, CFETs having different threshold voltages are formed. The lower gate electrodes of CFETs in different regions can be formed having different combinations of electrode layers such that each region has a different threshold voltage. The threshold voltage in each region can be tuned by controlling the properties of the various electrode layers. The embodiments described herein can allow for improved device scaling, improved flexibility of design, and reduced manufacturing cost.

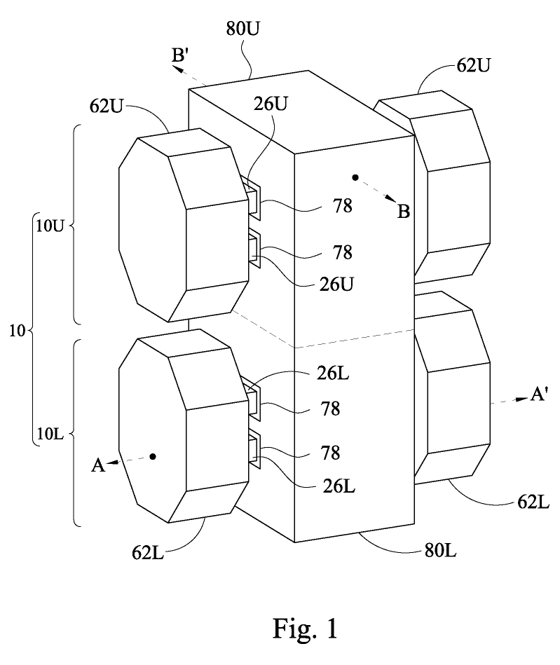

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor 10 includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. For example, the embodiments described below may include upper nanostructure-FETs 10U that are n-type devices and lower nanostructure-FETs 10L that are p-type devices. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., FinFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. The gate electrodes 80 may encircle semiconductor nanostructures 26. In some embodiments, different stacking transistors 10 may have lower gate electrodes 80L comprising different combinations of material layers. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A’ is a vertical cross-section that is parallel to a longitudinal axis of the semiconductor nanostructures 26 of a stacking transistor and in a direction of, for example, a current flow between the source/drain regions 62 of the stacking transistor. Cross-section B-B’ is a vertical cross-section that is perpendicular to cross-section A-A’ and along a longitudinal axis of a gate electrode 80 of the CFET. Subsequent figures may refer to these reference cross-sections for clarity.

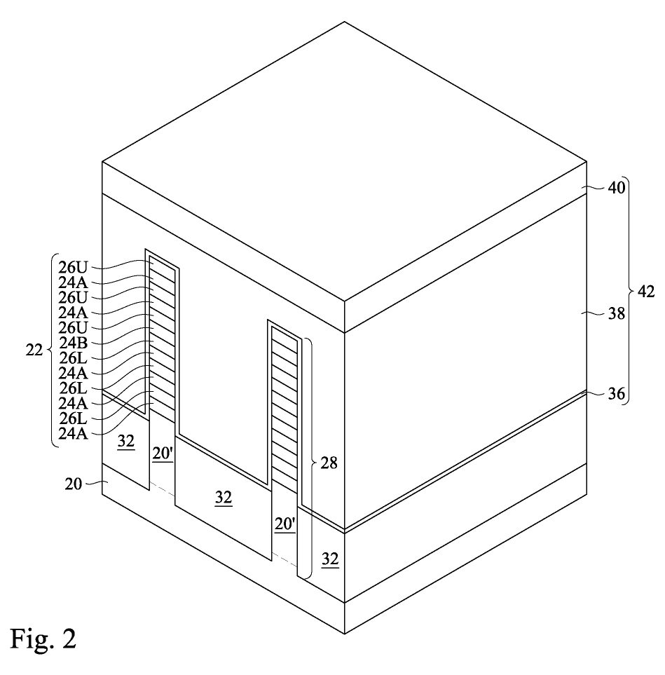

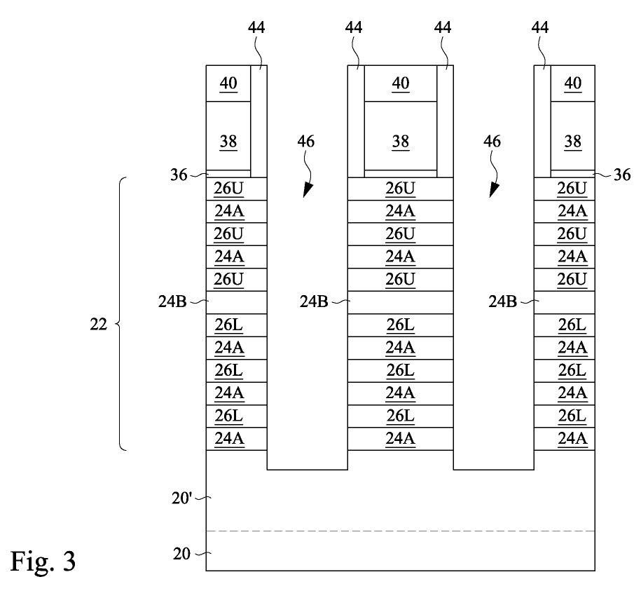

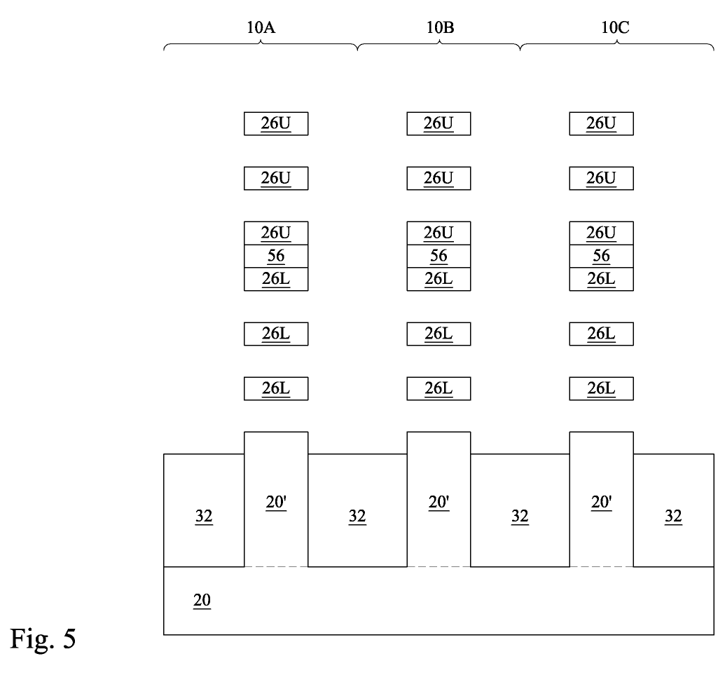

FIGS. 2 - 21 illustrate various views of intermediate stages in the formation of stacking transistors 10 (as schematically represented in FIG. 1) in accordance with some embodiments. FIGS. 3-4 and 20-21 illustrate vertical cross-sectional views along a similar cross-section as the vertical reference cross-section A-A’ of FIG. 1. FIGS. 5-19 illustrate vertical cross-sectional views along a similar cross-section as the vertical reference cross-section B-B’ of FIG. 1. FIG. 2 illustrates a three-dimensional view of a wafer, which includes substrate 20, in accordance with some embodiments. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strips 20’ (patterned portions of the semiconductor substrate 20, also referred to as semiconductor fins 20’) and a multi-layer stack 22. The stacked components or layers of the multi-layer stack 22 are referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B are formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor nanostructures 24B may be removed at a faster rate than the dummy semiconductor nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy semiconductor nanostructures 24B may be formed of germanium or silicon germanium with a larger atomic percentage of germanium than the dummy nanostructures 24A.

The lower semiconductor nanostructures 26L provide channel regions for lower nanostructure-FETs of the resulting CFETs. The upper semiconductor nanostructures 26U provide channel regions for upper nanostructure-FETs of the resulting CFETs. The semiconductor nanostructures 26 that are immediately above/below (e.g., in contact with) the dummy nanostructures 24B may be used for isolation and may or may not act as channel regions for the CFETs. The dummy nanostructures 24B are subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as a Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20’, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), a Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process or a grinding process. The material of dummy gate layer 38 be conductive or non-conductive, and may be selected from a group including amorphous silicon, polycrystalline-silicon (polysilicon), poly-crystalline silicon germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20’. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a desired depth.

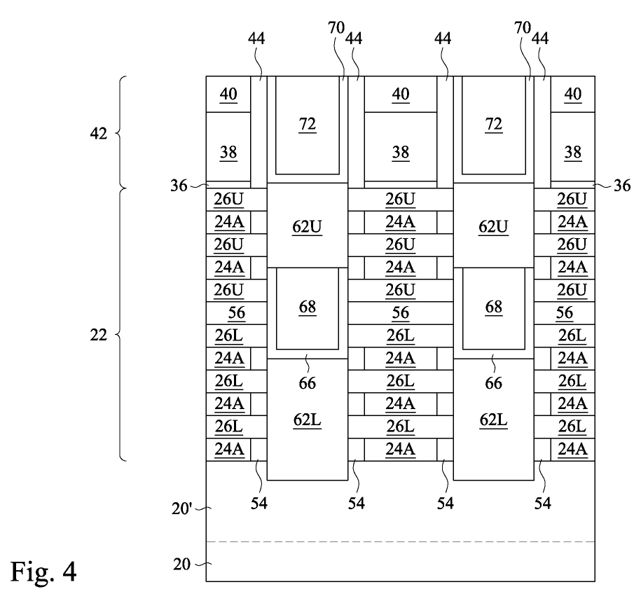

In FIG. 4, inner spacers 54 and dielectric isolation layers 56 are formed. Forming inner spacers 54 and dielectric isolation layers 56 may include performing an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer and depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 72. In the illustrated embodiment, the masks 40 remain after the removal process. In other embodiments, the masks 40 are removed such that the top surfaces of the dummy gates 38 are exposed through the second ILD 72.

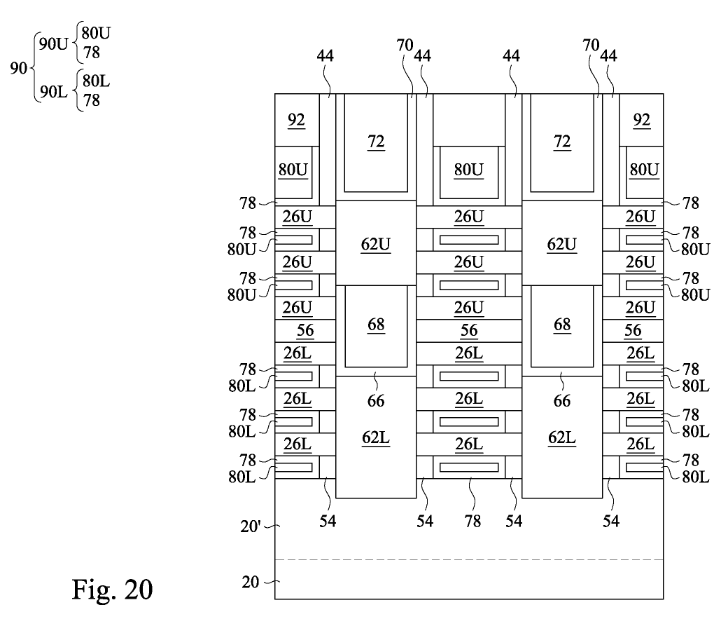

FIGS. 5 - 19 illustrate intermediate steps in a replacement gate process to replace the dummy gate stacks 42 and the dummy nanostructures 24A with gate structures 90, in accordance with some embodiments. The gate structures 90 include gate dielectrics 78 and gate electrodes 80. The gate electrodes 80 include upper gate electrodes 80U over lower gate electrodes 80L. FIGS. 5 - 18 illustrate intermediate steps in the formation of lower gate electrodes 80L, and FIG. 20 illustrates an intermediate step in the formation of upper gate electrodes 80U. FIGS. 5-19 illustrate the vertical cross-sectional views along a similar cross-section as the vertical reference cross-section B-B’ of FIG. 1. FIGS. 5-19 illustrate three adjacent regions 10A-C in which three corresponding CFETs are subsequently formed. Each region 10A-C includes a semiconductor strip 20’ with corresponding overlying semiconductor nanostructures 26. While the following process is described for an embodiment comprising three CFETs in three regions, the techniques may be applied to any number of CFETs. In other embodiments, a region 10A-C may comprise more than one CFET. In other embodiments, the regions 10A-C and their associated CFETs are not adjacent.

In FIG. 5, the dummy gate stacks 42 and the remaining portions of the dummy nanostructures 24A are removed, in accordance with some embodiments. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A are etched at a faster rate than the semiconductor nanostructures 26, the dielectric isolation layers 56, and the inner spacers 54. The etching may be isotropic. For example, when the dummy nanostructures 24A are formed of silicon germanium, and the semiconductor nanostructures 26 are formed of silicon, the etch process may include a wet etch process using tetramethylammonium hydroxide (TMAH), ammonium hydroxide (NH₄OH), or the like. Other etch processes are possible.

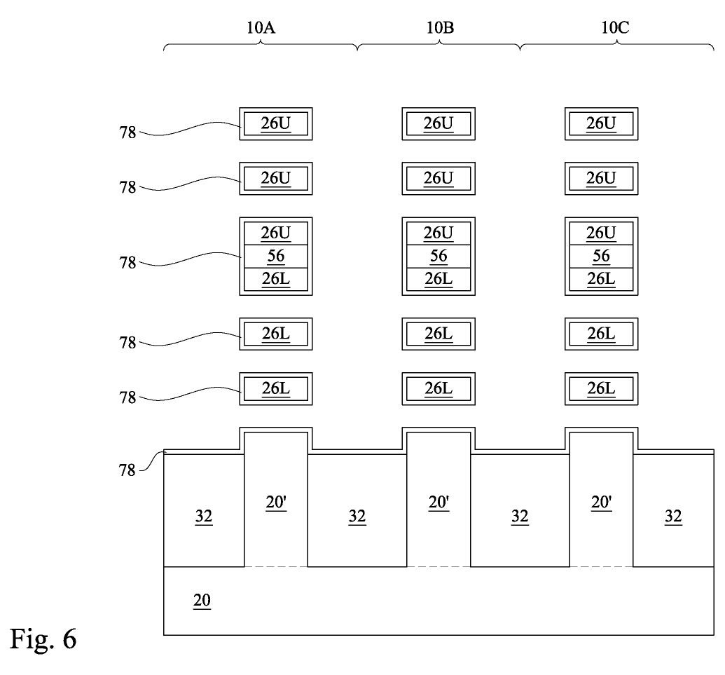

In FIG. 6, gate dielectrics 78 are deposited in the recesses between the gate spacers 44 and on the exposed semiconductor nanostructures 26, in accordance with some embodiments. The gate dielectrics 78 are conformally formed on exposed surfaces of the recesses including surfaces of the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor strips 20’; on the top surfaces, the sidewalls, and the bottom surfaces of the semiconductor nanostructures 26; and on the sidewalls of the gate spacers 44. The gate dielectrics 78 may or may not be formed on exposed sidewalls of the dielectric isolation layers 56, and are shown on sidewalls of the dielectric isolation layers 56 in the embodiment of FIG. 6. In some cases, the gate dielectrics 78 are formed on surfaces of the STI regions 32 exposed by the recesses. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and/or combinations thereof. The formation methods of the gate dielectrics 78 may include molecular-beam deposition (MBD), ALD, PECVD, or the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer. Other layers or materials are possible.

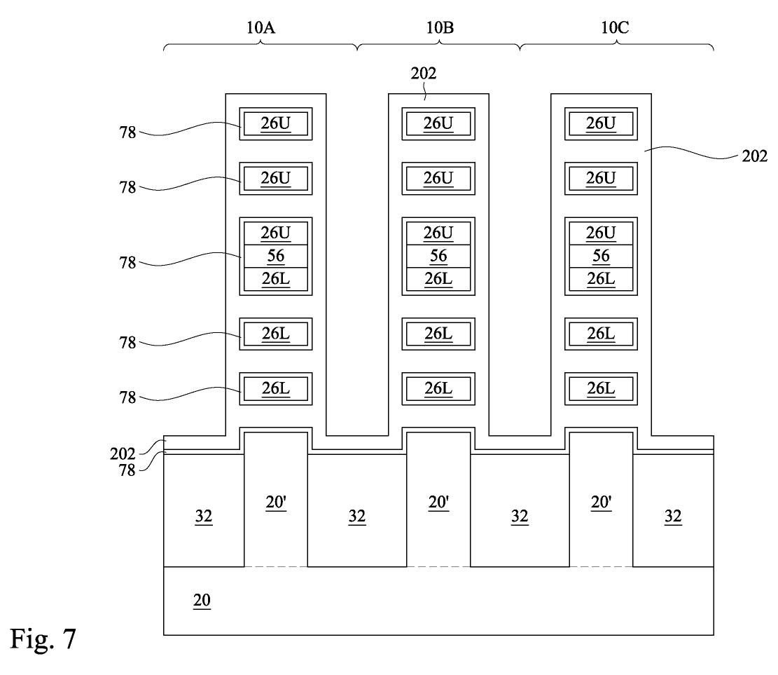

In FIG. 7, a dummy layer 202 is formed over the structure, in accordance with some embodiments. The dummy layer 202 is a temporary or sacrificial layer that protects portions of the structure during subsequent processing. The dummy layer 202 may be deposited on the gate dielectrics 78. The dummy layer 202 may wrap around the semiconductor nanostructures 26, and may fill regions between vertically adjacent semiconductor nanostructures 26, as shown in FIG. 7. The dummy layer 202 may also be deposited over the STI regions 32. In this manner, the dummy layer 202 may protect gate dielectrics 78 and semiconductor nanostructures 26 during formation of the gate electrodes 80. The dummy layer 202 may also be subsequently patterned to allow for the gate electrodes 80 in each region 10A-C to be formed having different compositions, described in greater detail below. The dummy layer 202 may be a suitable material having a high etching selectivity from the gate dielectrics 78, such as aluminum oxide, aluminum nitride, silicon nitride, silicon oxynitride, silicon oxycarbide, or the like. The dummy layer 202 may be formed using flowable CVD, ALD, or the like. In some embodiments, the dummy layer 202 is deposited using a conformal deposition process.

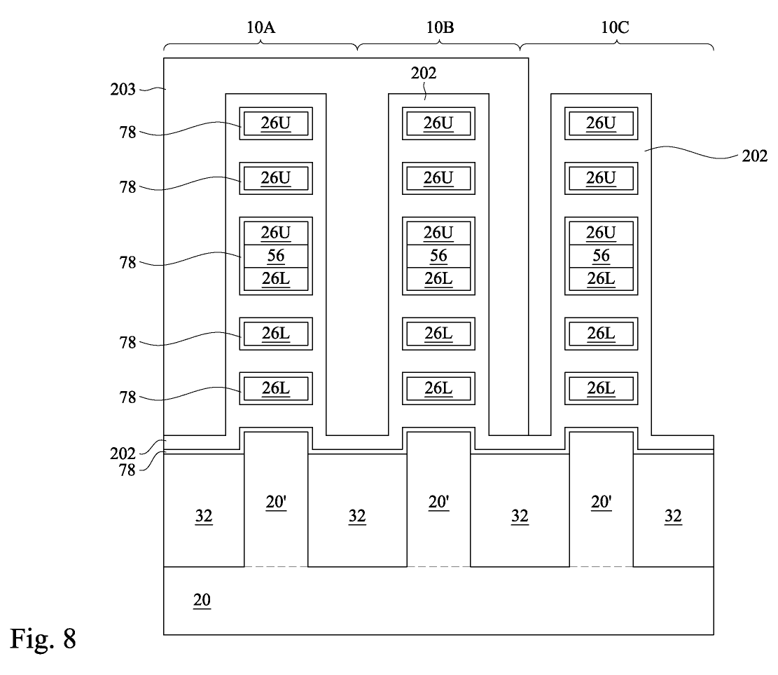

In FIG. 8, a photoresist 203 is deposited over the structure and patterned to expose region 10C, in accordance with some embodiments. The photoresist 203 may be a single-layer photoresist, a multi-layer photoresist structure, a hard mask, or the like, and may be deposited using suitable techniques such as CVD, ALD, spin-on, or the like. In some cases, the photoresist 203 comprises a Bottom Anti-Reflection Coating (BARC) or the like. The photoresist 203 may be patterned using suitable photolithographic techniques. The patterning forms an opening that exposes at least a portion of region 10C. For example, the dummy layer 202 surrounding the semiconductor nanostructures 26 of region 10C may be exposed by the opening in the patterned photoresist 203. In the embodiment of FIG. 8, the regions 10A and 10B remain at least partially covered by the photoresist 203 after patterning.

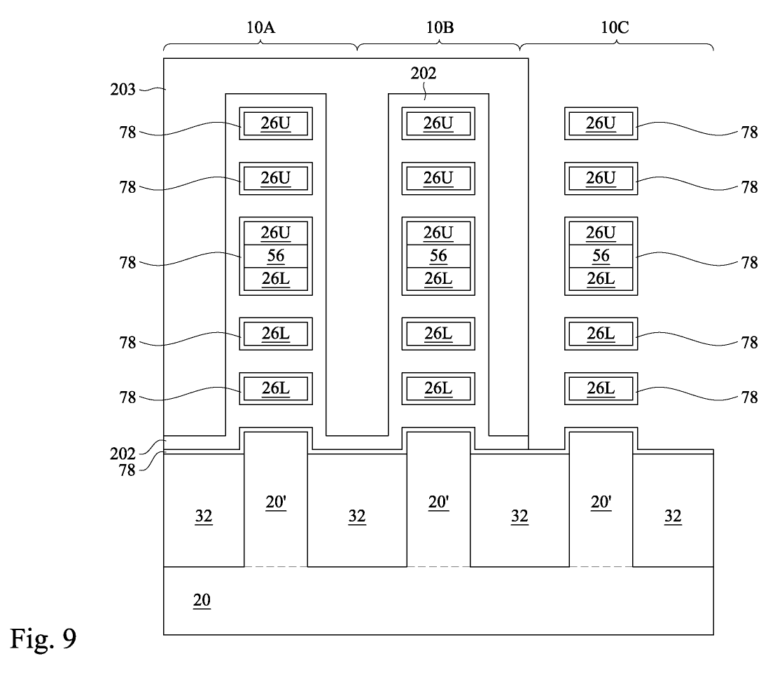

In FIG. 9, the dummy layer 202 in region 10C is removed, in accordance with some embodiments. An etching process may be performed to remove the dummy layer 202 exposed by the opening in the patterned photoresist 203. The etching process may include a wet etching process or a dry etching process, which may be isotropic. In some embodiments, the etching process may selectively etch the dummy layer 202 without significant etching of the gate dielectrics 78. For example, for embodiments in which the dummy layer 202 is aluminum oxide, the etching process may include a wet etch using a suitable etchant, such as ammonium hydroxide (NH₄OH), hydrochloric acid (HCl), or the like. Other etchants or etching processes are possible. In this manner, the gate dielectrics 78 in region 10C are exposed, while the gate dielectrics 78 in regions 10A and 10B remain covered by the photoresist 203 and the dummy layer 202.

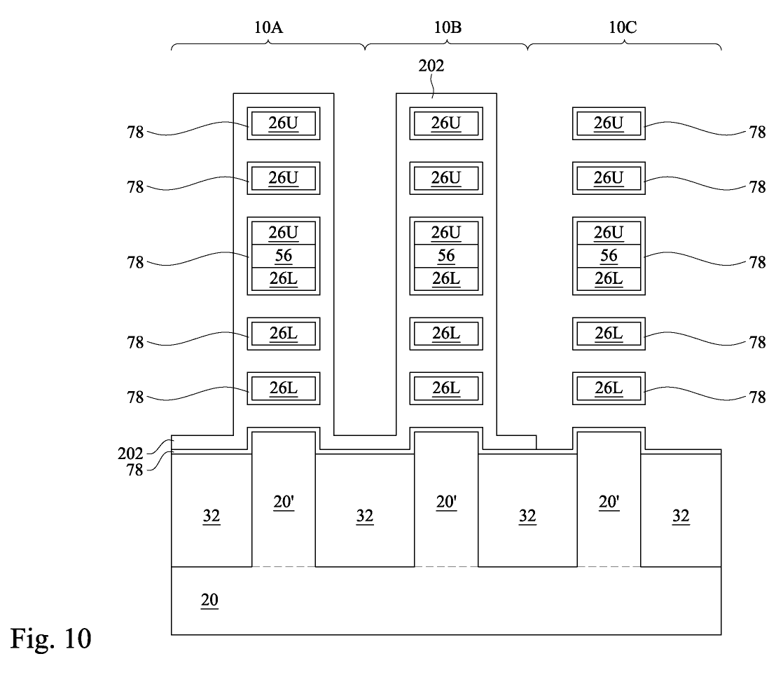

In FIG. 10, the photoresist 203 is removed, in accordance with some embodiments. The photoresist 203 may be removed using, for example, a suitable etching or ashing process. After removing the photoresist 203, the gate dielectrics 78 in region 10C are exposed, while the gate dielectrics 78 in regions 10A and 10B remain covered by the dummy layer 202.

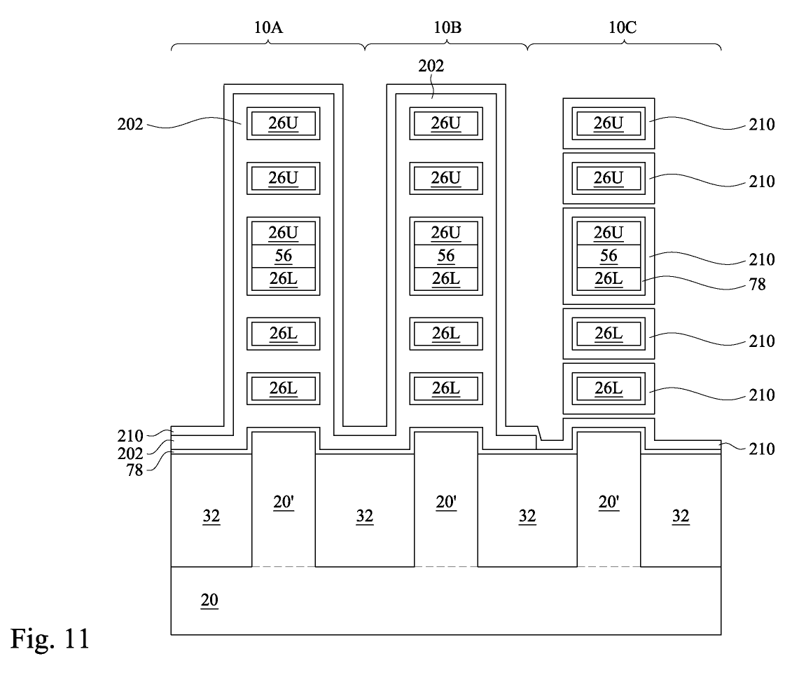

In FIG. 11, a first lower electrode layer 210 is deposited over the structure, in accordance with some embodiments. The first lower electrode layer 210 may comprise a work function tuning metal, and may also comprise any number of barrier layers, any number of glue layers, or other appropriate layers. The first lower electrode layer 210 is formed of material(s) that are suitable for the device type of the lower nanostructure-FETs, such as for a p-type nanostructure-FETs. In some embodiments, the first lower electrode layer 210 comprises a p-type work function tuning metal such as titanium nitride, tantalum nitride, titanium tungsten nitride, titanium silicon nitride, combinations thereof, or the like. The first lower electrode layer 210 may be formed using one or more conformal deposition processes, such as CVD, ALD, or the like. The first lower electrode layer 210 is deposited on the gate dielectrics 78 in region 10C, and on the dummy layer 202 in regions 10A and 10B. In some cases, the threshold voltage (Vt) of the lower nanostructure-FETs may be controlled by controlling the amount of tungsten in a first lower electrode layer 210 comprising titanium tungsten nitride. For example, increasing the atomic percentage of tungsten can increase the threshold voltage. In some embodiments, the first lower electrode layer 210 comprises titanium tungsten nitride having a tungsten atomic percentage in the range of about 5 % to about 20 %, which can allow for suitable threshold voltage tuning. Other compositions of the first lower electrode layer 210 are possible.

As shown in FIG. 11, the first lower electrode layer 210 wraps around the semiconductor nanostructures 26. The first lower electrode layer 210 is deposited between vertically adjacent semiconductor nanostructures 26, and may or may not fill the recesses between vertically adjacent semiconductor nanostructures 26, depending on the deposited thickness of the first lower electrode layer 210. For example, in the embodiment of FIG. 11, the first lower electrode layer 210 does not extend continuously between vertically adjacent semiconductor nanostructures 26, but in other embodiments the first lower electrode layer 210 may extend continuously between vertically adjacent semiconductor nanostructures 26. Other thicknesses are possible. In some embodiments, the threshold voltage (Vt) of a lower nanostructure-FET may be adjusted by depositing the first lower electrode layer 210 over the gate dielectrics 78. Further, in some embodiments, the threshold voltage of lower nanostructure-FETs in region 10C may be adjusted by controlling the thickness of the first lower electrode layer 210. In some embodiments, the first lower electrode layer 210 may be formed having a thickness in the range of about 5 Å to about 25 Å, which can allow for suitable threshold voltage tuning.

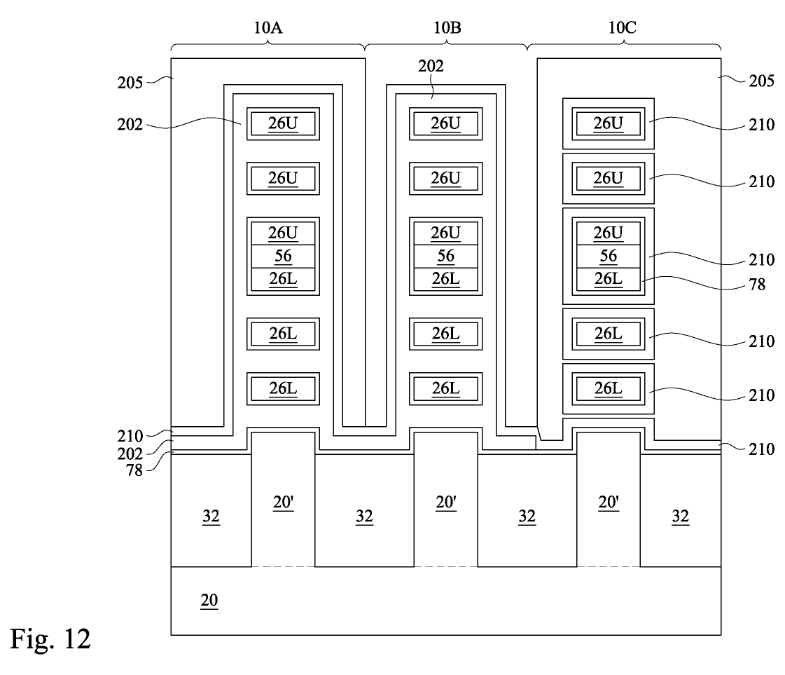

In FIG. 12, a photoresist 205 is deposited over the structure and patterned to expose region 10B, in accordance with some embodiments. The photoresist 205 may be similar to the photoresist 203. For example, in some cases, the photoresist 205 comprises a BARC or the like. The photoresist 205 may be patterned using suitable photolithographic techniques. The patterning forms an opening that exposes at least a portion of region 10B. For example, the first lower electrode layer 210 on the dummy layer 202 in region 10B may be exposed by the opening in the patterned photoresist 205. In the embodiment of FIG. 12, the regions 10A and 10B remain at least partially covered by the photoresist 205 after patterning.

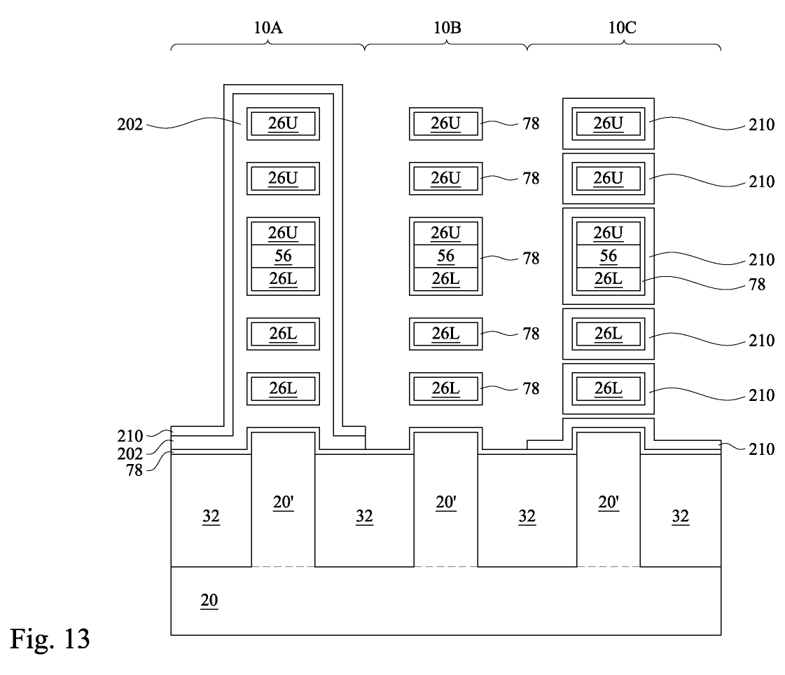

In FIG. 13, the first lower electrode layer 210 and the dummy layer 202 in region 10B are removed, in accordance with some embodiments. One or more etching processes may be performed to remove the first lower electrode layer 210 and the dummy layer 202 exposed by the opening in the patterned photoresist 205. The etching process(es) may include a wet etching process or a dry etching process, which may be similar to those described previously for FIG. 9. In some embodiments, the etching process(es) may selectively etch the dummy layer 202 and/or the first lower electrode layer 210 without significant etching of the gate dielectrics 78. In this manner, the gate dielectrics 78 in region 10B are exposed, while the regions 10A and 10C are protected by the photoresist 205. After removing the dummy layer 202, the photoresist 205 is removed using a suitable etching or ashing process. After removing the photoresist 205, the gate dielectrics 78 in region 10B are exposed, and the first lower electrode layer 210 in regions 10A and 10C are exposed.

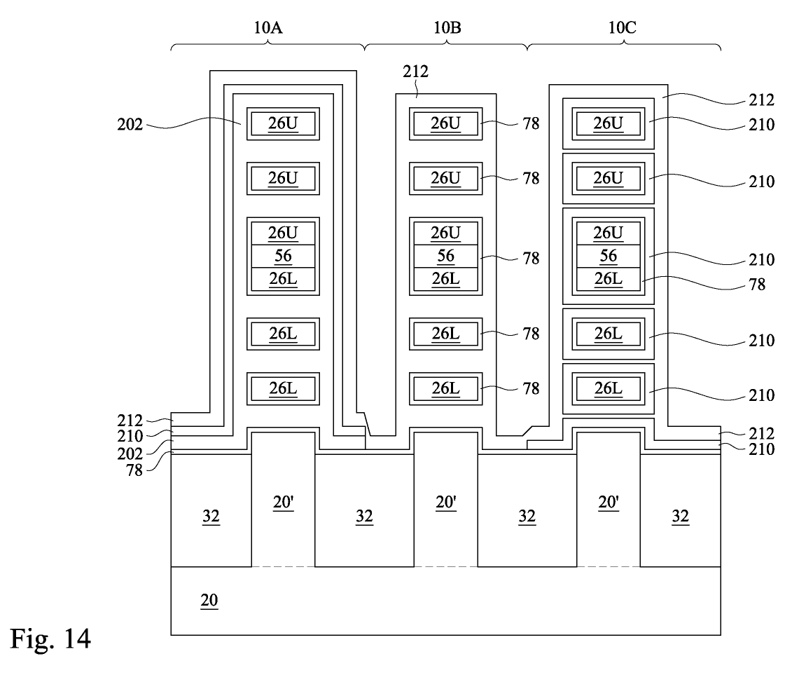

In FIG. 14, a second lower electrode layer 212 is deposited over the structure, in accordance with some embodiments. The second lower electrode layer 212 is deposited on the gate dielectrics 78 in the region 10B and on the first lower electrode layer 210 in the regions 10A and 10C. The second lower electrode layer 212 may comprise a work function tuning metal, and may also comprise any number of barrier layers, any number of glue layers, or other appropriate layers. The second lower electrode layer 212 is formed of material(s) that are suitable for the device type of the lower nanostructure-FETs, such as for a p-type nanostructure-FETs. In some embodiments, the second lower electrode layer 212 comprises a p-type work function tuning metal, which may be similar to those described previously for the first lower electrode layer 210. For example, in some embodiments, the second lower electrode layer 212 comprises a p-type work function tuning metal such as titanium nitride, tantalum nitride, titanium tungsten nitride, titanium silicon nitride, combinations thereof, or the like. In some embodiments, the second lower electrode layer 212 and the first lower electrode layer 210 comprise the same p-type work function tuning metal. In other embodiments, the second lower electrode layer 212 and the first lower electrode layer 210 comprise different p-type work function tuning metals or p-type work function tuning metals having different compositions. For example, in some embodiments in which the second lower electrode layer 212 and the first lower electrode layer 210 comprise titanium tungsten nitride, the tungsten atomic percentage of the second lower electrode layer 212 may be different than that of the first lower electrode layer 210. The second lower electrode layer 212 may be deposited using techniques similar to those described previously for the first lower electrode layer 210. In some cases, the second lower electrode layer 212 extends continuously from the region 10B to the region 10C.

FIG. 14 illustrates the second lower electrode layer 212 as filling the recesses between vertically adjacent semiconductor nanostructures 26 in region 10B. In other embodiments, the second lower electrode layer 212 wraps around the semiconductor nanostructures 26 in region 10B while leaving recesses between vertically adjacent semiconductor nanostructures 26, similar to the illustrated first lower electrode layer 210. Accordingly, the second lower electrode layer 212 may or may not fill the recesses between vertically adjacent semiconductor nanostructures 26 in the region 10B, depending on the deposited thickness of the second lower electrode layer 212. In some embodiments, the second lower electrode layer 212 may be formed having a thickness in the range of about 5 Å to about 25 Å, though other thicknesses are possible. The second lower electrode layer 212 may fill any recesses between vertically adjacent nanostructures 26 in the region 10C, as shown in FIG. 14. In some embodiments, the threshold voltage (Vt) of a lower nanostructure-FET may be adjusted by depositing the second lower electrode layer 212 over the gate dielectrics 78 or over the first lower electrode layer 210. Further, in some embodiments, the threshold voltage of lower nanostructure-FETs in regions 10B and 10C may be adjusted by controlling the thickness of the second lower electrode layer 212.

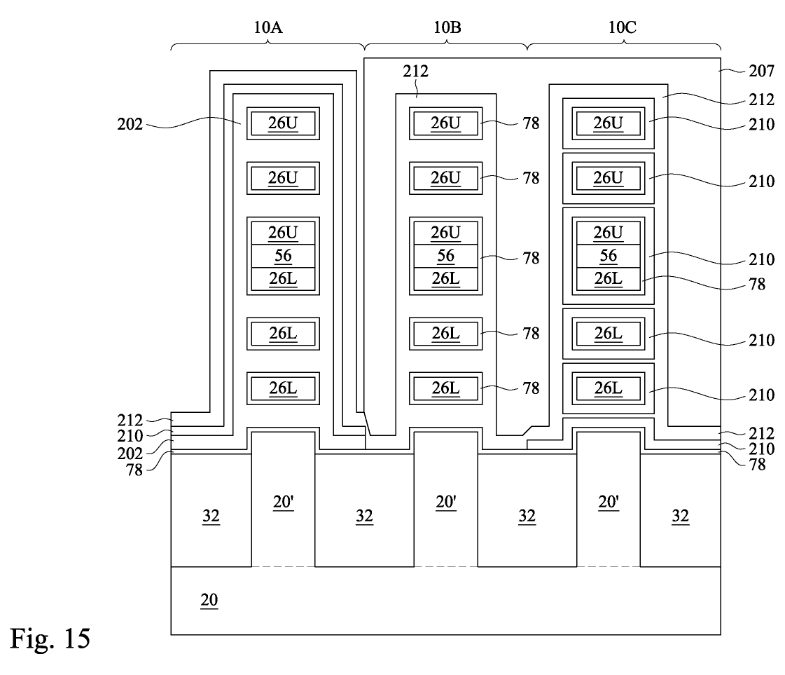

In FIG. 15, a photoresist 207 is deposited over the structure and patterned to expose region 10A, in accordance with some embodiments. The photoresist 207 may be similar to the photoresist 203 or the photoresist 205. For example, in some cases, the photoresist 207 comprises a BARC or the like. The photoresist 207 may be patterned using suitable photolithographic techniques. The patterning forms an opening that exposes at least a portion of region 10A. For example, the second lower electrode layer 212 in region 10A may be exposed by the opening in the patterned photoresist 207. In the embodiment of FIG. 15, the regions 10C and 10B remain at least partially covered by the photoresist 207 after patterning.

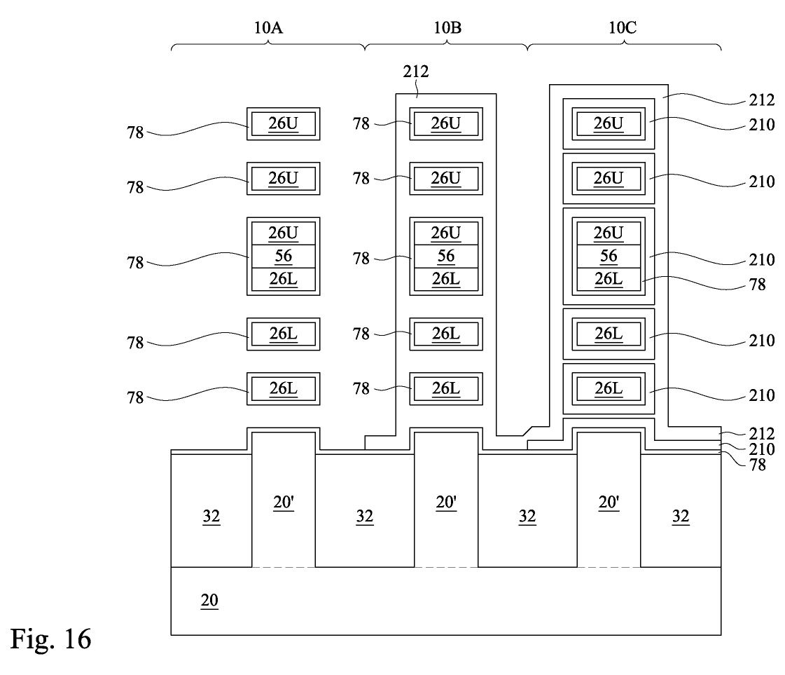

In FIG. 16, the first lower electrode layer 210, the second lower electrode layer 212, and the dummy layer 202 in region 10A are removed, in accordance with some embodiments. One or more etching processes may be performed to remove the first lower electrode layer 210, the second lower electrode layer 212, and the dummy layer 202 exposed by the opening in the patterned photoresist 207. The etching process(es) may include a wet etching process or a dry etching process, which may be similar to those described previously for FIG. 9. In some embodiments, the etching process(es) may selectively etch the dummy layer 202, the first lower electrode layer 210, and/or the second lower electrode layer 212 without significant etching of the gate dielectrics 78. In this manner, the gate dielectrics 78 in region 10A are exposed, while the regions 10B and 10C are protected by the photoresist 207. After performing the etching process(es), the photoresist 207 is removed using a suitable etching or ashing process. After removing the photoresist 207, the gate dielectrics 78 in region 10A are exposed, the second lower electrode layer 212 in region 10B is exposed, and the first lower electrode layer 210 in region 10C is exposed.

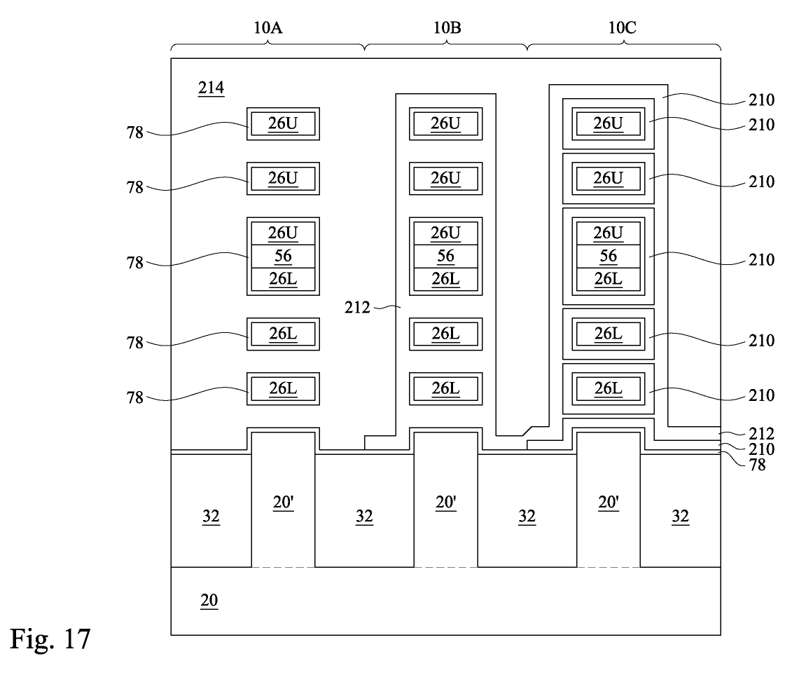

In FIG. 17, a third lower electrode layer 214 is deposited over the structure, in accordance with some embodiments. The third lower electrode layer 214 is deposited over regions 10A, 10B, and 10C. In this manner, the third lower electrode layer 214 covers the gate dielectrics 78 in region 10A, the second lower electrode layer 212 in region 10B, and the first lower electrode layer 210 in region 10C. The third lower electrode layer 214 wraps around the semiconductor nanostructures 26 in 10A and fills the recesses between vertically adjacent semiconductor nanostructures 26 in region 10A. The third lower electrode layer 214 may include any number of work function tuning layers, any number of barrier layers, any number of glue layers, and a fill material. For example, in some embodiments, the third lower electrode layer 214 comprises a metal-containing fill material such as tungsten, titanium, titanium nitride, tantalum, tantalum nitride, tantalum carbide, aluminum, ruthenium, cobalt, combinations thereof, multi-layers thereof, or the like. In some embodiments, the third lower electrode layer 214 comprises materials similar to the first lower electrode layer 210 or the second lower electrode layer 212. The third lower electrode layer 214 may be deposited using suitable techniques, such as CVD, PECVD, ALD, the like, or a combination thereof. In some embodiments, the first lower electrode layer 210 and the second lower electrode layer 212 comprise titanium tungsten nitride, and the third lower electrode layer 214 comprises titanium nitride. In some embodiments, the third lower electrode layer 214 may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

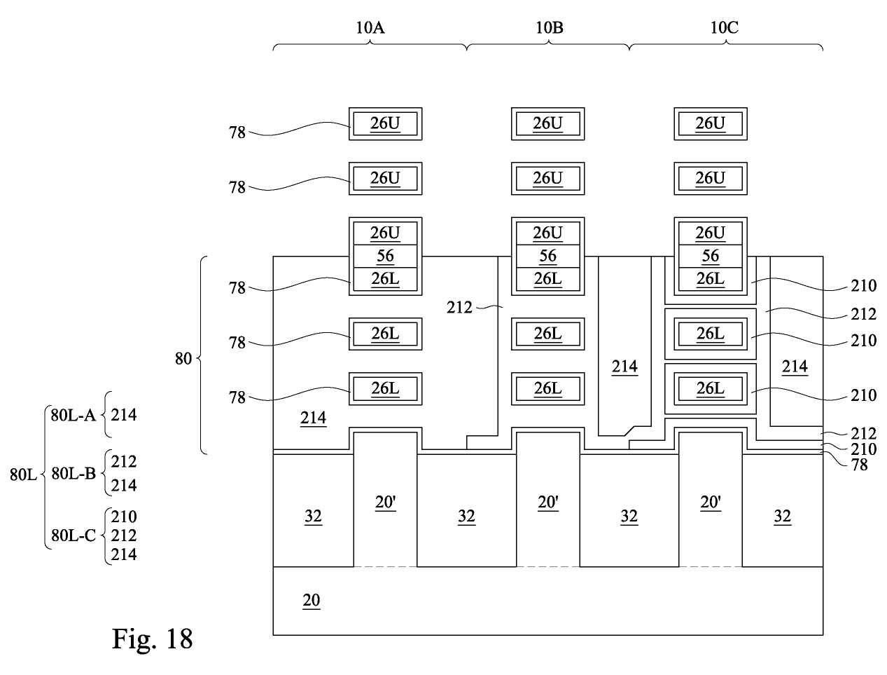

In FIG. 18, upper portions of the first lower electrode layer 210, the second lower electrode layer 212, and the third lower electrode layer 214 are recessed to form lower gate electrodes 80L, in accordance with some embodiments. The lower gate electrodes 80L formed for regions 10A, 10B, and 10C are indicated as lower gate electrodes 80L-A, 80L-B, and 80L-C, respectively. The upper portions of the first lower electrode layer 210, the second lower electrode layer 212, and the third lower electrode layer 214 may be recessed using one or more etching processes, which may include a dry etch, a wet etch, or a combination thereof. The etching processes may include an isotropic etch, in some cases. The remaining portions of the first lower electrode layer 210, the second lower electrode layer 212, and the third lower electrode layer 214 form the lower gate electrodes 80L. The exposed top surface of the lower gate electrodes 80L may include exposed top surfaces of the first lower electrode layer 210, the second lower electrode layer 212, and the third lower electrode layer 214. After performing the etching processes, gate dielectrics 78 on the upper semiconductor nanostructures 26U in regions 10A-C are exposed. In some embodiments, a height of the lower gate electrodes 80L is above a lower semiconductor nanostructure 26L and below an upper semiconductor nanostructure 26U. In other words, a top surface of the lower gate electrodes 80L may be laterally aligned with the dielectric isolation layers 56, as shown in FIG. 18.

The lower gate electrode 80L-A of the region 10A includes the third lower electrode layer 214; the lower gate electrode 80L-B of the region 10B includes the second lower electrode layer 212 and the third lower electrode layer 214; and the lower gate electrode 80L-C of the region 10C includes the first lower electrode layer 210, the second lower electrode layer 212, and the third lower electrode layer 214. Thus, the techniques described herein allow for the formation of lower gate electrodes different regions 10A-C that have different compositions. The different regions may be contiguous, like regions 10A-C, or may be separated. The different gate electrodes having different compositions, may also have different properties. For example, the lower nanostructure-FETs in the regions 10A, 10B, and 10C may have different threshold voltages due to the different combinations of lower electrode layers in each of the gate electrodes 80L-A, 80L-B, and 80L-C. As described previously, the presence of the first lower electrode layer 210 and/or the second lower electrode layer 212 can alter the threshold voltage of the lower nanostructure-FETs. Thus, the addition of the first lower electrode layer 210 to region 10C can cause the threshold voltage of region 10C to be different from that of region 10A or of region 10B. Similarly, the addition of the second lower electrode layer 212 to regions 10B and 10C can cause the threshold voltages of regions 10B and 10C to be different from that of region 10A.

In some cases, the threshold voltage can be controlled by controlling the thickness of the first lower electrode layer 210 and/or the thickness of the second lower electrode layer 212. In this manner, the threshold voltage in region 10B can be controlled by controlling the thickness of the second lower electrode layer 212. For example, the threshold voltage can be controlled by controlling the thickness ratio between the third lower electrode layer 214 and the combined thickness of the second lower electrode layer 212. Additionally, the threshold voltage in region 10B can be controlled by controlling the composition of the second lower electrode layer 212. For example, for embodiments in which the second lower electrode layer 212 comprises tungsten, the threshold voltage may be controlled by controlling the tungsten atomic percentage. Other compositions or elements are possible that may be controlled to control the threshold voltage. In this manner, in some cases, the second lower electrode layer 212 in region 10B can effectively act as a work function tuning layer.

In some cases, the first lower electrode layer 210 and the second lower electrode layer 212 in region 10C can effectively act as a single thicker work function tuning layer. Thus, the threshold voltage in region 10C can be controlled by controlling the individual thicknesses and/or the combined thickness of the first lower electrode layer 210 and the second lower electrode layer 212. For example, the threshold voltage can be controlled by controlling the thickness ratio between the third lower electrode layer 214 and the combined thickness of the first lower electrode layer 210 and the second lower electrode layer 212. In some embodiments, the first lower electrode layer 210 and the second lower electrode layer 212 have a combined thickness in the range of about 20 Å to about 35 Å, though other thicknesses are possible. Additionally, the threshold voltage in region 10B can be controlled by controlling the composition of the first lower electrode layer 210 and/or the second lower electrode layer 212. For example, for embodiments in which the first lower electrode layer 210 and second lower electrode layer 212 comprise tungsten, the threshold voltage may be controlled by controlling the tungsten atomic percentage of the first lower electrode layer 210 and/or the second lower electrode layer 212, or by controlling the overall tungsten atomic percentage of the first lower electrode layer 210 and the second lower electrode layer 212, collectively. Other compositions or elements are possible that may be controlled to control the threshold voltage. In this manner, the lower nanostructure-FETs in the regions 10A-C may each be formed to have different threshold voltages, which can be separately controlled by controlling the properties of the first lower electrode layer 210, the second lower electrode layer 212, and the third lower electrode layer 214. While each region 10A-C has a single lower nanostructure-FET, more than one lower nanostructure-FET may be formed in each region 10A-C, with the lower nanostructure-FETs of the regions 10A-C having the threshold voltage associated with that region 10A-C. In other embodiments, more than three lower gate electrode layers may be deposited. For example, another lower gate electrode layer may be deposited over one or more of the regions 10A-C, or additional regions with other combinations of gate electrode layers may be formed. In this manner, more than three regions may have more than three associated threshold voltages.

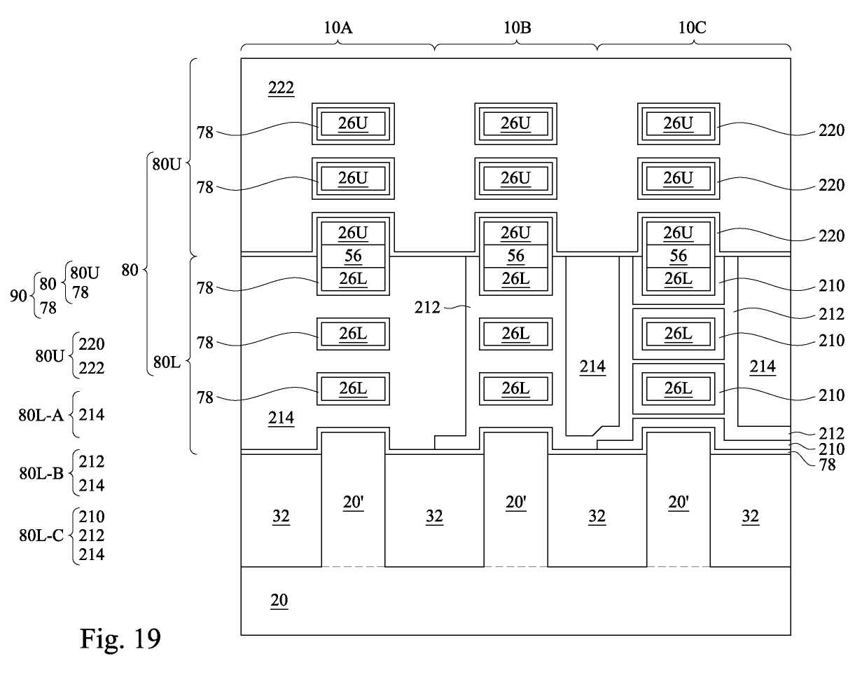

In FIG. 19, upper gate electrodes 80U are formed on the lower gate electrodes 80L in the regions 10A-C, in accordance with some embodiments. The upper gate electrodes 80U are disposed between the upper semiconductor nanostructures 26U in the regions 10A-C. In some embodiments, the upper gate electrodes 80U wrap around the upper semiconductor nanostructures 26U. The upper gate electrodes 80U may include any number of work function tuning layers 220 and a fill material 222. The upper gate electrodes 80U may also include any number of barrier layers, any number of glue layers, or other suitable layers (not illustrated). The upper gate electrodes 80U are formed of materials that are suitable for the device type of the upper nanostructure-FETs. For example, the upper gate electrodes 80U may include one or more work function tuning layers 220 formed of material(s) that are suitable for the device type of the upper nanostructure-FETs. For example, for embodiments in which the upper nanostructure-FETs are n-type devices, the upper gate electrodes include an n-type work function tuning layer 220, which may be formed of titanium aluminum, titanium aluminum carbide, tantalum aluminum, tantalum carbide, combinations thereof, or the like. The upper gate electrodes 80U may be formed of a metal-containing fill material such as tungsten, titanium, titanium nitride, tantalum, tantalum nitride, tantalum carbide, aluminum, ruthenium, cobalt, combinations thereof, multi-layers thereof, or the like. In some cases, the upper gate electrodes 80U may be formed of the same candidate materials and candidate processes for forming the lower gate electrodes 80L. Other materials are possible. The layers of the upper gate electrodes 80U may be formed using suitable deposition techniques, such as CVD, PECVD, ALD, the like, or a combination thereof. In some embodiments, the upper gate electrodes 80U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 80U may be different than the dipole-inducing elements of the lower gate electrodes 80L. In this manner, gate electrodes comprising upper gate electrodes 80U and lower gate electrodes 80L may be formed.

In some embodiments, gate isolation regions (not illustrated) are formed to divide (or “cut”) at least some of the gate structures 90 (including the gate dielectrics 78 and the gate electrodes 80) into multiple gate segments. As an example to form the gate isolation regions, openings may be patterned in the gate structures 90. For example, openings may be patterned between the gate structures 90 of two adjacent regions 10A, 10B, or 10C. Any acceptable etching process, such as a dry etch, a wet etch, the like, or a combination thereof, may be performed to pattern the openings. The etching may be anisotropic. One or more dielectric material(s) are deposited in the openings. Acceptable dielectric materials include silicon nitride, silicon oxide, silicon oxynitride, or the like, which may be formed by a deposition process such as CVD, ALD, or the like. A removal process may be performed to remove the excess portions of the dielectric material(s), which excess portions are over the top surfaces of the gate electrodes 80, thereby forming the gate isolation regions. In some embodiments, a planarization process such as a chemical mechanical polish (CMP), an etch-back process, combinations thereof, or the like is utilized. A gate isolation region may isolate the gate structures 90 of adjacent devices, such as the gate structures 90 between two adjacent regions 10A, 10B, or 10C.

Additionally, a removal process may be performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially level or coplanar (within process variations). Each respective pair of a gate dielectric 78 and a gate electrode 80 (including an upper gate electrode 80U and/or a lower gate electrode 80L) may be collectively referred to as a “gate stack” 90 or a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor strip 20’.

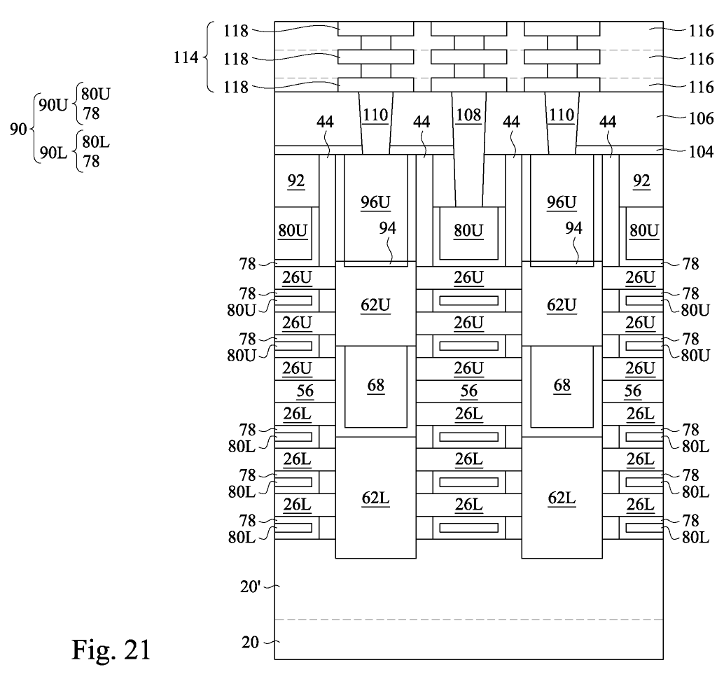

FIGS. 20-21 illustrate vertical cross-sectional views along a similar cross-section as the vertical reference cross-section A-A’ of FIG. 1. FIGS. 20-21 may represent a cross-section through any of regions 10A, 10B, or 10C. In FIG. 20, gate masks 92 are formed over the gate stacks 90, in accordance with some embodiments. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

In FIG. 21, metal-semiconductor alloy regions 94 and upper source/drain contacts 96U are formed through the second ILD 72 to electrically couple to the upper epitaxial source/drain regions 62U. As an example to form the upper source/drain contacts 96U, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the upper source/drain contacts 96U in the openings. In some embodiments, a planarization process such as a CMP, an etch-back process, combinations thereof, or the like is utilized. After the planarization process, the top surfaces of the gate spacers 44, the second ILD 72, and the upper source/drain contacts 96U are substantially coplanar (within process variations).

Optionally, metal-semiconductor alloy regions 94 are formed at the interfaces between the source/drain regions 62 and the upper source/drain contacts 96U. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the upper source/drain contacts 96U by depositing a metal in the openings for the upper source/drain contacts 96U and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the upper source/drain contacts 96U, such as from surfaces of the metal-semiconductor alloy regions 94. The material(s) of the upper source/drain contacts 96U can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon nitride, silicon oxynitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, upper gate contacts 108 and upper source/drain vias 110 are formed to contact the upper gate electrodes 80U and the upper source/drain contacts 96U, respectively. As an example to form the upper gate contacts 108 and the upper source/drain vias 110, openings for the upper gate contacts 108 and the upper source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the upper gate contacts 108 and the upper source/drain vias 110 in the openings. The upper gate contacts 108 and the upper source/drain vias 110 may be formed in distinct processes, or may be formed in the same process. Although shown as being formed in the same cross-section, it should be appreciated that each of the upper gate contacts 108 and the upper source/drain vias 110 may be formed in different cross-sections, which may avoid shorting of the contacts.

Still referring to FIG. 21, a front-side interconnect structure 114 is formed, in accordance with some embodiments. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers. The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower source/drain regions 80L may be made through a back side of the device (e.g., a side opposite to the front-side interconnect structure 114).

Embodiments described herein may achieve advantages. The techniques described herein allow for multiple stacked transistors having different threshold voltages to be formed using the same process steps. The stacked transistors may be, for example, Complementary Field-Effect Transistor (CFETs) such as vertically stacked complementary nanostructure-FETs. The embodiments described herein allow for the formation of lower nanostructure-FETs in two, three, or more than three regions, with each region having a different corresponding threshold voltage. The different threshold voltages are formed by selectively depositing different layers in different regions when forming the lower gate electrodes of the stacked transistors. In some cases, lower p-type nanostructure-FETs in different regions may be formed having different threshold voltages. The threshold voltages of the stacked transistors may be controlled or adjusted by controlling the composition, thickness, or number of lower gate electrode layers. The embodiments described herein can allow for reduced manufacturing cost, improved design flexibility, smaller device size, and improved device performance.

In an embodiment of the present disclosure, a method includes forming first nanostructures over a first region of a substrate; forming second nanostructures over a second region of the substrate; forming third nanostructures over a third region of the substrate; depositing a first gate electrode layer on the first nanostructures; depositing a second gate electrode layer on the second nanostructures and on the first gate electrode layer on the first nanostructures; depositing a third gate electrode layer on the third nanostructures, on the second gate electrode layer on the second nanostructures, and on the second gate electrode layer on the first nanostructures; and depositing a fourth gate electrode layer on the third gate electrode layer, on the first nanostructures, on the second nanostructures, and on the third nanostructures. In an embodiment, the method includes depositing a dummy material over the first nanostructures, the second nanostructures, and the third nanostructures; before depositing the first gate electrode layer, removing the dummy material from the first region; after depositing the first gate electrode layer, removing the dummy material from the second region; and after depositing the second gate electrode layer, removing the dummy material from the third region. In an embodiment, removing the dummy material from the second region includes depositing a photoresist over the first region, the second region, and the third region; patterning the photoresist to expose the second region; and performing an etching process to remove the dummy material. In an embodiment, the second nanostructures are free of the first gate electrode layer. In an embodiment, the second gate electrode layer is a work function tuning layer. In an embodiment, the second gate electrode layer is titanium tungsten nitride having a tungsten atomic percentage in the range of 5 % to 20 %. In an embodiment, the method includes, before depositing the fourth gate electrode layer, removing upper portions of the first gate electrode layer, the second gate electrode layer, and the third gate electrode layer. In an embodiment, the second region and the third region are contiguous.

In an embodiment of the present disclosure, a method includes forming first lower nanostructures over a substrate; forming second lower nanostructures over the substrate adjacent the first lower nanostructures; forming first upper nanostructures over the first lower nanostructures; forming second upper nanostructures over the second lower nanostructures; forming a first work function tuning layer on the first lower nanostructures, wherein the second lower nanostructures are free of the first work function tuning layer; forming a second work function tuning layer on the second lower nanostructures and on the first work function tuning layer; forming a first electrode fill material on the second work function tuning layer; forming a third work function tuning layer on the first upper nanostructures and on the second upper nanostructures; and forming a second electrode fill material on the third work function tuning layer. In an embodiment, the method includes depositing the first work function tuning layer over the second lower nanostructures; and before forming the second work function tuning layer, removing the first work function tuning layer from over the second lower nanostructures. In an embodiment, the second work function tuning layer encircles the second nanostructures. In an embodiment, the method includes forming third lower nanostructures over the substrate, wherein the third lower nanostructures are free of the first work function tuning layer and the second work function tuning layer, wherein the first electrode fill material is formed on the third lower nanostructures. In an embodiment, the first work function tuning layer includes a p-type work function tuning metal. In an embodiment, the first work function tuning layer and the second work function tuning layer include a same material. In an embodiment, the first work function tuning layer and the second work function tuning layer have a combined thickness in the range of 20 Å to 35 Å.

In an embodiment of the present disclosure, a device includes a first stacked transistor over a substrate, the first stacked transistor including: a first nanostructure over a second nanostructure; a first lower gate structure over the second nanostructure, the first lower gate structure including: a first gate electrode material encircling the second nanostructure; a second gate electrode material on the first gate electrode material; and a third gate electrode material on the second gate electrode material; and a first upper gate structure over the first nanostructure; and a second stacked transistor adjacent the first stacked transistor, the second stacked transistor including: a third nanostructure over a fourth nanostructure; a second lower gate structure over the fourth nanostructure, the second lower gate structure comprising: the second gate electrode material encircling the fourth nanostructure; and the third gate electrode material on the second gate electrode material; and a second upper gate structure over the third nanostructure. In an embodiment, the second gate electrode material of the first lower gate structure is continuous with the second gate electrode material of the second lower gate structure. In an embodiment, the first stacked transistor includes a n-type transistor that includes the first nanostructure. In an embodiment, the third gate electrode material is titanium nitride. In an embodiment, the first stacked transistor includes a first p-type transistor that includes the second nanostructure, wherein the second stacked transistor includes a second p-type transistor that includes the fourth nanostructure, wherein the first p-type transistor has a first threshold voltage and the second p-type transistor has a second threshold voltage that is different from the first threshold voltage.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a stack of first nanostructures, a stack of second nanostructures, and a stack of third nanostructures over a substrate;
a first work function layer along the stack of first nanostructures;
a second work function layer along the stack of second nanostructures and along the first work function layer along the stack of first nanostructures; and
a gate electrode material along the stack of third nanostructures, along the second work function layer along the stack of second nanostructures, and along the second work function layer along the first work function layer.

2. The device of claim 1, further comprising a stack of fourth nanostructures over the stack of first nanostructures, wherein the first work function layer is closer to the substrate than the stack of fourth nanostructures.

3. The device of claim 1, wherein the second work function layer encircles at least one first nanostructure and encircles at least one second nanostructure.

4. The device of claim 1, wherein the second work function layer extends continuously from along the stack of second nanostructures to along the first work function layer along the stack of first nanostructures.

5. The device of claim 1, wherein the first work function layer is a p-type work function layer.

6. The device of claim 1, wherein top surfaces of the first work function layer, the second work function layer, and the gate electrode material are level.

7. The device of claim 1, wherein the first work function layer and the second work function layer comprise titanium and nitrogen.

8. A device comprising:
a first nanostructure over a substrate;
a second nanostructure over the substrate and adjacent to the first nanostructure;
a third nanostructure over the substrate and adjacent to the second nanostructure; and
a gate structure surrounding the first nanostructure, the second nanostructure, and the third nanostructure, wherein the gate structure comprises:
a gate dielectric layer surrounding the first nanostructure, the second nanostructure, and the third nanostructure;
a gate electrode layer surrounding the first nanostructure;
a first work function layer surrounding the second nanostructure and surrounding the third nanostructure, wherein the first work function layer is between the gate electrode layer and the second nanostructure; and
a second work function layer surrounding the third nanostructure, wherein the second work function layer is between the first work function layer and the third nanostructure.

9. The device of claim 8, wherein the gate dielectric layer surrounding the second nanostructure is free of the second work function layer.

10. The device of claim 8, wherein the second work function layer extends between the third nanostructure and the substrate.

11. The device of claim 8, wherein the first nanostructure is in a first region over the substrate, wherein the second nanostructure is in a second region over the substrate, wherein the first region over the substrate and the second region over the substrate are free of the second work function layer.

12. The device of claim 8, wherein the first work function layer and the second work function layer are a same material.

13. The device of claim 8, wherein the first work function layer and the second work function layer have different concentrations of tungsten.

14. The device of claim 8, wherein the gate structure has a first work function value for the first nanostructure, a second work function value for the second nanostructure, and a third work function value for the third nanostructure, wherein the first work function value, the second work function value, and the third work function value are different values.

15. A method comprising:
forming a first nanostructure stack, a second nanostructure stack, and a third nanostructure stack over a substrate, wherein the first nanostructure stack comprises a first upper nanostructure over a first lower nanostructure, wherein the second nanostructure stack comprises a second upper nanostructure over a second lower nanostructure, wherein the third nanostructure stack comprises a third upper nanostructure over a third lower nanostructure;
forming a first mask covering the first nanostructure stack and the second nanostructure stack;
depositing a first gate electrode layer over the first mask over the first nanostructure stack, over the first mask over the second nanostructure stack, and over the third nanostructure stack;
removing the first mask from over the second nanostructure stack;
depositing a second gate electrode layer over the first mask over the first nanostructure stack, over the second nanostructure stack, and over first gate electrode layer over the third nanostructure stack;
removing the first mask from over the first nanostructure stack; and
depositing a third gate electrode layer over the first nanostructure stack, over the second gate electrode layer over the second nanostructure stack, and over the second gate electrode layer over the third nanostructure stack.

16. The method of claim 15, further comprising recessing the first gate electrode layer, the second gate electrode layer, and the third gate electrode layer such that top surfaces of the first gate electrode layer, the second gate electrode layer, and the third gate electrode layer are closer to the substrate than the first upper nanostructure, the second upper nanostructure, and the third upper nanostructure.

17. The method of claim 16, further comprising depositing a fourth gate electrode layer over the third gate electrode layer, second gate electrode layer, the first gate electrode layer, the first upper nanostructure, the second upper nanostructure, and the third upper nanostructure.

18. The method of claim 15, wherein removing the first mask from over the first nanostructure stack removes the first gate electrode layer from over the first nanostructure stack and removes the second gate electrode layer from over the first nanostructure stack.

19. The method of claim 15, wherein the first mask comprises aluminum oxide.

20. The method of claim 15, further comprising forming a dielectric isolation layer between the first lower nanostructure and the first upper nanostructure.
